(19) United States
(12) Patent Application Publication
(10) Pub. No.: US 2013/0289903 A1
(43) Pub. Date: Oct. 31, 2013

(54) RESOURCE MANAGEMENT SYSTEM

(71) Applicants: Hiroki Kazuno, Osaka (JP); Tomoya Sogo, Osaka (JP)

(72) Inventors: Hiroki Kazuno, Osaka (JP); Tomoya Sogo, Osaka (JP)

(73) Assignee: PANASONIC CORPORATION, Osaka (JP)

(21) Appl. No.: 13/979,893

(22) PCT Filed: Jan. 20, 2012
(86) PCT No.: PCT/JP2012/051143

§ 371 Date: Jul. 16, 2013

(30) Foreign Application Priority Data
Jan. 20, 2011 (JP) 2011-010079

(51) Int. Cl. G01R 21/00

(52) U.S. Cl. CPC G01R 21/00
USPC 702/60

(57) ABSTRACT

A collective setting part sets a collective usage permission period for lighting loads, and a separate setting part sets a separate usage permission period for the lighting loads. The relevance information memory stores relevance information that is obtained by relating each of starting times and ending times of the separate usage permission periods to a starting time or an ending time of the collective usage permission period. When the collective usage permission period is modified through a user terminal, the separate setting part modifies the starting times and the ending times of the separate usage permission periods so as to interlock with modified content for the starting time or the ending time of the collective usage permission period related in the relevance information.

### TECHNICAL FIELD

The invention relates generally to resource management systems and, more particularly, to a resource management system used for energy saving diagnosis.

### BACKGROUND ART

There has been a resource management system, which monitors electricity used by each load (electrical equipment, such as, a lighting device or an air conditioner), in office buildings, commercial facilities such as foods supermarkets, or buildings such as factories (predetermined spaces) (e.g., see the following Patent literature 1).

Also, there is a resource management system, which sets in advance a usage permission period during which use of electricity is permitted as an operational plan for each load, and generates an electricity usage state, in which it can be determined whether actual use of electricity is performed within the usage permission period or performed out of the usage permission period, and displays the electricity usage state on a monitoring screen. Then, it is necessary for such a resource management system to set an operational plan in order to distinguish the usage permission period during which the use of the electricity is permitted from a usage non-permission period during which the use of the electricity is not permitted.

The conventional operational plan setting includes a separate setting in which the usage permission period (a starting time and an ending time for the usage permission period) is set for each load, and a collective setting in which the same usage permission period is set for all loads. Hereinafter, the usage permission period that is separately set for each load is called a separate usage permission period, and the usage permission period that is collectively set for all loads is called a collective usage permission period. When the distinction between the separate and collective usage permission periods is not needed, it is called the usage permission period.

FIG. 15 shows one example of a monitoring screen located in a foods supermarket. An electricity usage state of each lighting load from hour 0 (midnight at the start of the day) to hour 24 (midnight at the end of the day) is shown on the monitoring screen. The lighting loads are located at various areas, such as a lobby, a cash register, a vegetable section, a fresh fish section, a meat section and a backyard, in the foods supermarket. The electricity usage state is displayed for each lighting load. In the electricity usage state, a plurality of cells are displayed, each of which is obtained by dividing 24 hours by units of 30 minutes, and are color-coded about whether or not use of electricity at the time period is appropriate.

In FIG. 15, a collective usage permission period T111 is set with respect to the vegetable section, the fresh fish section and the meat section, and a separate usage permission period T112 is set with respect to the lobby, the cash register and the backyard. Cells that represent a time period corresponding to the collective usage permission period T111 are surrounded with a frame (in FIG. 15, it is a broken line with which the collective usage permission period T111 is surrounded). The collective usage permission period T111 is set as “a starting time=9:30 and an ending time=20:30” that includes the opening hours in the foods supermarket. Cells that represent a time period corresponding to the separate usage permission period T112 are surrounded with a frame (in FIG. 15, it is an alternate long and short dash line with which the separate usage permission period T112 is surrounded). The separate usage permission period T112 is separately set for each of the lobby, the cash register and the backyard.

Here, cells that correspond to time periods during which the lighting devices had used electricity within the collective usage permission period T111 and the separate usage permission period T112 are defined as an appropriate usage time zone Taa. On the other hand, cells that correspond to time periods during which the lighting devices had used electricity out of those periods T111, T112 are defined as an inappropriate usage time zone Tbb. The appropriate usage time zone Taa and the inappropriate usage time zone Tbb are displayed by different colors. In the case of FIG. 15, the appropriate usage time zone Taa is represented by diagonal lines and the inappropriate usage time zone Tbb is represented by dots, due to black and white presentation. In addition, cells that correspond to time periods during which electricity had not been used are displayed without colors.

The collective and separate usage permission periods T111, T112, set as described above, can be modified independently of each other.

Further, the resource management system has an interlock setting function that modifies the separate usage permission periods T112 so as to interlock with the modified content for the collective usage permission period T111, when the collective usage permission period T111, set as described above, is modified. For example, FIG. 15 shows the monitoring screen before the modification of the collective usage permission period T111, and FIG. 16 shows the monitoring screen after the modification of the collective usage permission period T111. In FIG. 16, the collective usage permission period T111 is modified from “the starting time=9:30 and the ending time=20:30” in FIG. 15 into “the starting time=8:30 and the ending time=21:30”. Then, when only starting times of the separate usage permission periods T112 are modified so as to interlock with the modified content for the collective usage permission period T111, the starting times of the separate usage permission periods T112 for the lobby, the cash register and backyard are modified into “8:30” that is the same as the starting time of the collective usage permission period T111 (see FIG. 16).

### PRIOR ART DOCUMENTS

### Patent Literature

Patent literature 1: Japanese patent application publication No. 8-50501

### SUMMARY OF THE INVENTION

### Problems to be Resolved by the Invention

However, the above-mentioned interlock setting function has the following problems.

Generally, the lighting load at a selling space, such as the vegetable section, the fresh fish section or the meat section, is lit during the opening hours, such as daytime. In contrast, the lighting load at the backyard, where receiving operation and preliminary operation are performed, is lit outside of the opening hours, such as nighttime. Accordingly, the usage permission periods in the selling space and the backyard are set as shown in FIG. 17(a) for example. In the selling space, the collective usage permission period T111 is set as “the starting time=9:30 and the ending time=20:30”. In the backyard, the separate usage permission period T112 is set as “the starting time=18:00 and the ending time=10:00”.

Thus, when the time periods for the collective and separate usage permission periods T111, T112 are set so as to be reversal of each other, the following problem occurs when the interlock setting is performed.

For example, as shown in FIG. 17(b), a case is considered where the collective usage permission period T111 is modified from “the starting time=9:30 and the ending time=20:30” into “the starting time=10:00 and the ending time=18:00”. when only the starting time of the separate usage permission period T112 is modified so as to interlock with the modified content for the collective usage permission period T111, the starting time of the separate usage permission period T112 in the backyard is modified into “10:00” that is the same as that of the collective usage permission period T111 (see FIG. 17(b)).

Thus, the separate usage permission period T112 in the backyard in which the starting time is modified into “10:00” is set as “the starting time=10:00 and the ending time=10:00”, and therefore, the usage permission period becomes 24 hours. After this interlock setting, the separate usage permission period T112 “the starting time=10:00 and the ending time=10:00” includes also the opening hours during which the lighting load is not lit generally for the backyard, thereby working against energy saving. That is, conventionally, there has been no interlock pattern available for the case where the time periods for the collective and separate usage permission periods T111, T112 are set so as to be reversal of each other. Therefore, there has been a problem that the usage permission period does not fit with actual resource consumption states, after the interlock setting.

Further, in the case where the collective usage permission period T111 is modified, there are needs for various interlock patterns in regard to the interlock setting in which the separate usage permission period T112 is modified so as to interlock with the modified content for the collective usage permission period T111. For example, there is an interlock setting adapted to daylight-saving time, an interlock setting depending on climate (the case of an air-conditioning load in particular,), or the like. However, there has been no resource management system being available for needs for such various interlock patterns.

So, a resource management system is desired, which is available for needs for various interlock patterns, such as the case where the time periods for the collective and separate usage permission periods T111, T112 are set so as to be reversal of each other, or the interlock setting adapted to daylight-saving time.

It is an object of the invention to provide a resource management system, which is available for needs for various interlock patterns in regard to the interlock setting in which the separate usage permission periods are modified so as to interlock with modified content for the collective usage permission period.

### Means of Solving the Problems

A resource management system of the present invention monitors a usage period during which a resource is used by each operation of a plurality of loads located in a predetermined space, and comprises: an information acquisition unit periodically acquiring information relating to usage state of the resource, as usage information; a data generation unit generating data of usage permission periods during which use of the resource is permitted; a period setting unit setting a usage permission period for each of the plurality of loads based on data of the usage permission periods generated by the data generation unit; a determination unit determining whether or not the use of the resource corresponding to the usage information acquired by the information acquisition unit is performed within the usage permission period; and a display unit displaying the usage period of the resource so as to distinguish whether or not the usage period of the resource is within the usage permission period, using the determination result of the determination unit, wherein the data generation unit generates data of one first usage permission period, and data of one or more second usage permission periods, wherein the period setting unit comprises: a collective setting part setting the first usage permission period collectively, as usage permission periods for all of the plurality of loads; a separate setting part setting the second usage permission periods separately, as usage permission periods for loads, among the plurality of loads; a relevance information memory storing relevance information that is obtained by relating each of starting times and ending times of the second usage permission periods to a starting time or an ending time of the first usage permission period; and a relevance information registry registering the relevance information in the relevance information memory, wherein the collective setting part does not set the first usage permission period as usage permission periods for loads to which the second usage permission periods have been set, when performing the collective setting, and wherein when the data generation unit modifies the first usage permission period, the separate setting part is configured to modify the starting times and the ending times of the second usage permission periods so as to interlock with modified content for the starting time or the ending time of the first usage permission period related in the relevance information.

In the invention, preferably, the relevance information registry registers the relevance information in the relevance information memory based on each of setting contents that are set for the starting time and the ending time of the first usage permission period and the starting times and the ending times of the second usage permission periods.

In the invention, preferably, when the data generation unit modifies the first usage permission period, the separate setting part is configured to shift the starting times and the ending times of the second usage permission periods by a time difference between times before and after the modification for the starting time or the ending time of the first usage permission period related in the relevance information.

In the invention, preferably, when the data generation unit modifies the first usage permission period so as to be shortened, if a reduced time length for the first usage permission period is equal to or more than a time length of a second usage permission period, among the second usage permission periods, the relevance information registry is configured to free the relationship between the starting time and the ending time of the second usage permission period and the starting time and the ending time of the first usage permission period.

In the invention, preferably, when the data generation unit modifies the first usage permission period so as to be shortened, if a reduced time length for the first usage permission period is equal to or more than a time length of a second usage permission period, among the second usage permission periods, the collective setting part is configured to set the first usage permission period as the usage permission period for a load corresponding to the second usage permission period.

### Effect of the Invention

As explained above, the invention has an effect that the resource management system is available for needs for various interlock patterns in regard to the interlock setting in which the separate usage permission periods are modified so as to interlock with modified content for the collective usage permission period.

### BRIEF DESCRIPTION OF THE DRAWINGS

FIGS. 1(a) and 1(b) are configuration diagrams showing a system according to an embodiment.

FIG. 2 is a block diagram showing a configuration of a user terminal in the system according to the embodiment.

FIG. 3 is a plane view showing one example of a monitoring screen in the system according to the embodiment.

FIG. 4 is a plane view showing the monitoring screen when a collective setting is performed in the system according to the embodiment.

FIG. 5 is a plane view showing the monitoring screen for load groups in the system according to the embodiment.

FIGS. 6(a) to 6(c) are a plane view showing a setting processing for separate usage permission periods in the system according to the embodiment.

FIG. 7 is a table structure diagram showing relevance information in the system according to the embodiment.

FIG. 8 is a plane view showing the monitoring screen before an interlock setting in the system according to the embodiment.

FIG. 9 is a plane view showing the monitoring screen after the interlock setting in the system according to the embodiment.

FIG. 10(a) is a plane view showing another monitoring screen before the interlock setting, and FIG. 10(b) is a plane view showing another monitoring screen after the interlock setting, in the system according to the embodiment.

FIG. 11(a) is a plane view showing another monitoring screen before the interlock setting, and FIG. 11(b) is a plane view showing another monitoring screen after the interlock setting, in the system according to the embodiment.

FIG. 12 is a table structure diagram showing relevance information before and after the interlock setting in the system according to the embodiment.

FIG. 13(a) is a plane view showing another monitoring screen before the interlock setting, and FIG. 13(b) is a plane view showing another monitoring screen after the interlock setting, in the system according to the embodiment.

FIG. 14 is a flow chart showing an auto-registration processing for the relevance information in the system according to the embodiment.

FIG. 15 is a plane view showing a monitoring screen before an interlock setting in a conventional system.

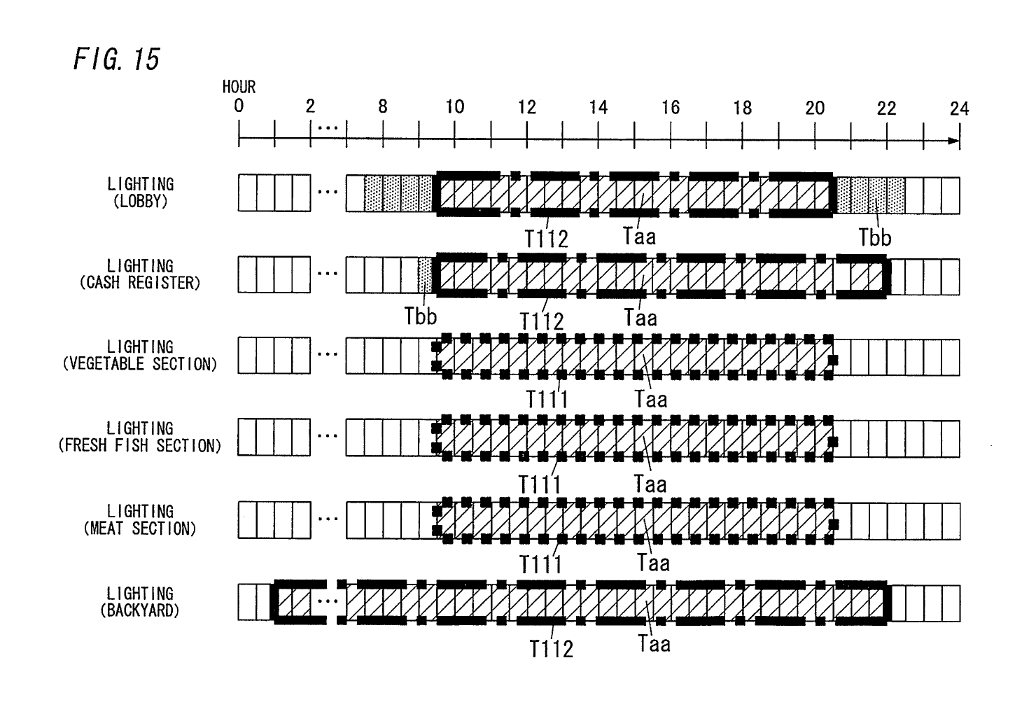

FIG. 16 is a plane view showing the monitoring screen after the interlock setting in the conventional system.

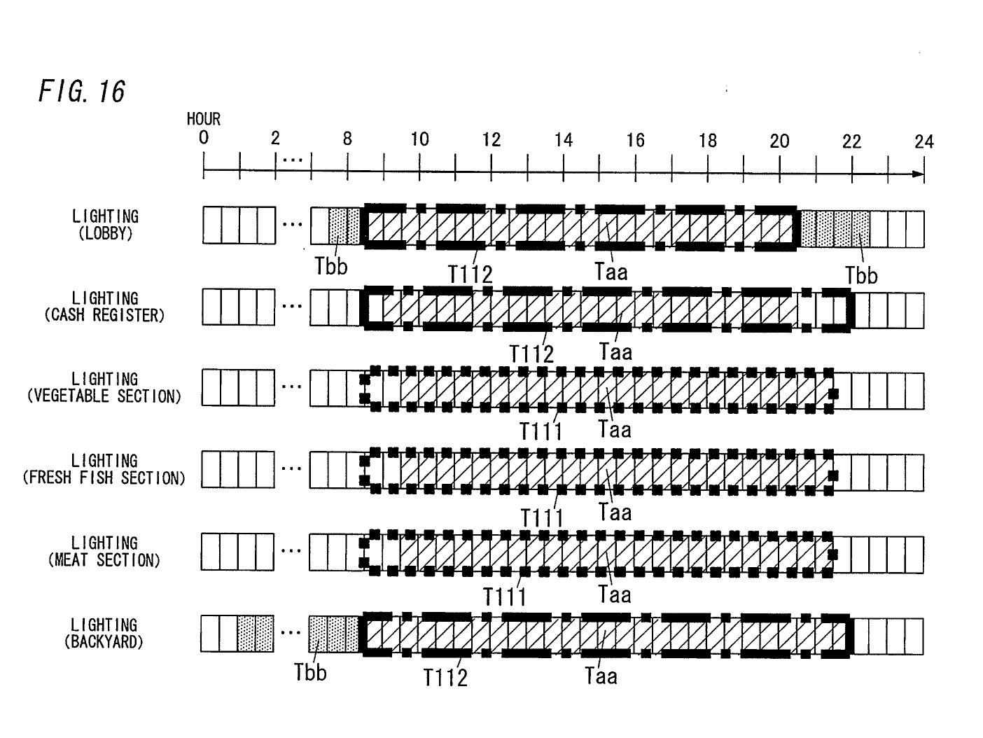

FIG. 17(a) is a plane view showing the monitoring screen before the interlock setting, and FIG. 17(b) is a plane view showing the monitoring screen after the interlock setting, in the conventional system.

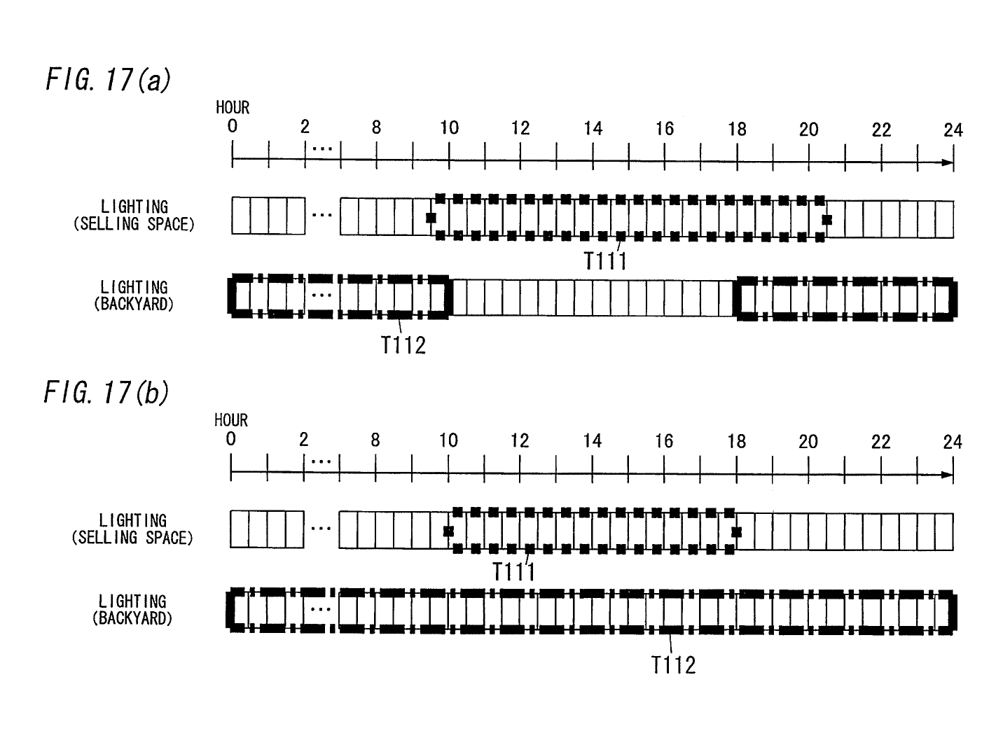

### BEST MODE FOR CARRYING OUT THE INVENTION

An embodiment of the invention will be explained below, referring to Figures.

### Embodiment

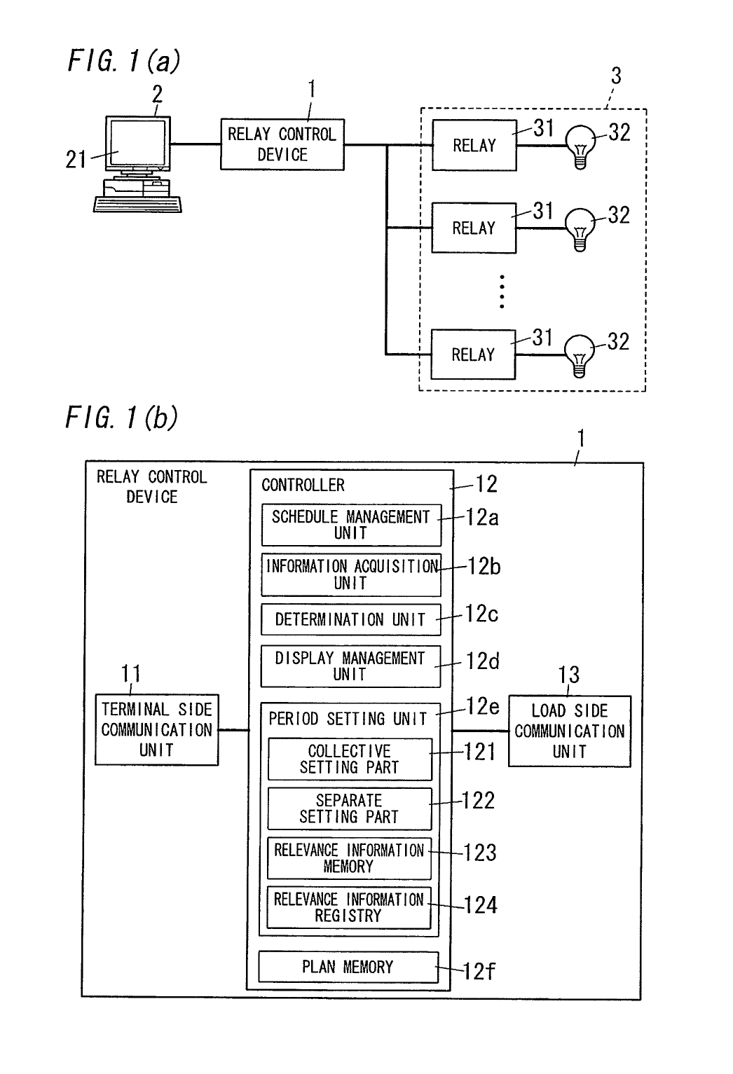

A resource management system according to the present embodiment monitors a usage period during which a resource is used by each operation of a plurality of loads. As shown in FIG. 1(a), the resource management system according to the present embodiment includes a relay control device 1 and a user terminal 2, and is connected to a lighting system 3. In this case, the resource management system monitors at least the usage period for the resource, such as electricity, gas, water or heat. As one example, a case where the resource is electricity will be explained below.

The lighting system 3 includes a plurality of groups, each of which includes a relay 31 and a lighting load 32. Each lighting load 32 is turned on and off in response to ON/OFF of the corresponding relay 31.

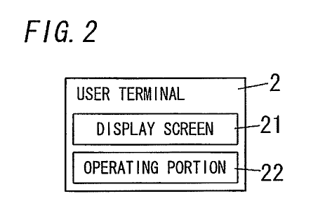

The user terminal 2 is a computer, such as a personal computer, and includes a display screen 21 constituted by an LCD and the like, and an operating portion 22 constituted by a keyboard, a mouse and the like, as shown in FIG. 2. The user terminal 2 displays the lighting state of each lighting load 32 that has been collected by the relay control device 1, through a web browser or the like, on the display screen 21. That is, the user terminal 2 displays the usage period of electricity so as to distinguish whether or not the usage period of electricity is within a usage permission period, using the determination result of a determination unit 12c described below. The display screen 21 corresponds to a display unit of the invention.

The user terminal 2 displays the usage state of electricity for every predetermined periods (e.g., for every 30 minutes). In a case where the predetermined period is 30 minutes for example, when electricity had been used for even a short time (e.g., 1 minute) in 30 minutes, the user terminal 2 displays the usage state so if electricity had been used during the whole predetermined period in question. That is, in a case where electricity had been used for a short time, the user terminal 2 displays the usage state in an area corresponding to the predetermined period in question, in the same manner as a case where electricity had been used for 30 minutes.

As shown in FIG. 1(b), the relay control device 1 includes a terminal side communication unit 11, a controller 12 and a load side communication unit 13, and communicates with each of the plurality of relays 31 by using a time-division multiplexing transmission method.

The controller 12 includes a schedule management unit 12a, an information acquisition unit 12b, a determination unit 12c, a display management unit 12d, a period setting unit 12e and a plan memory 12f.

The schedule management unit 12a controls ON/OFF of a relay 31 designated through schedule information (a designated time, a designated condition) that has been set in advance, thereby controlling lighting of the corresponding lighting load 32.

The information acquisition unit 12b communicates with each relay 31 periodically via the load side communication unit 13, in order to acquire an ON/OFF state of each relay 31. That is, the information acquisition unit 12b continually acquires the information relating to the ON/OFF state of each relay 31, thereby monitoring the ON/OFF state of each relay 31. Because the ON/OFF state of a relay 31 is linked with the lighting state of the corresponding lighting load 32, the information acquisition unit 12b can monitor the lighting states of the lighting loads 32 through monitoring the ON/OFF states of the relays 31. Therefore, the information acquisition unit 12b can periodically acquire, as usage information, information relating to the usage state of electricity used by operation of each lighting load 32, thereby monitoring the usage period of electricity.

Further, for each lighting load 32, a usage permission period, during which use of electricity is permitted, is set as an operational plan in response to the installation location or the like. In this case, the usage permission period means a period (a time period) during which lighting is permitted. Data of the usage permission period for each lighting load 32 is stored in the plan memory 12f.

The determination unit 12c refers to the plan memory 12f, and determines whether or not the usage period of electricity is within the usage permission period, when the relay 31 is switched on and the lighting load 32 is lit. That is, the determination unit 12c determines that use of electricity within the usage permission period is appropriate and use of electricity out of the usage permission period is inappropriate.

The display management unit 12d generates data (monitoring image data), in order to display the information relating to the lighting state of each lighting load 32 (the ON/OFF state of each relay 31) together with the determination result of the determination unit 12c through the user terminal 2, and then transmits the generated monitoring image data to the user terminal 2 via the terminal side communication unit 21. The user terminal 2 displays the received monitoring image data on the display screen 21 (a monitoring screen).

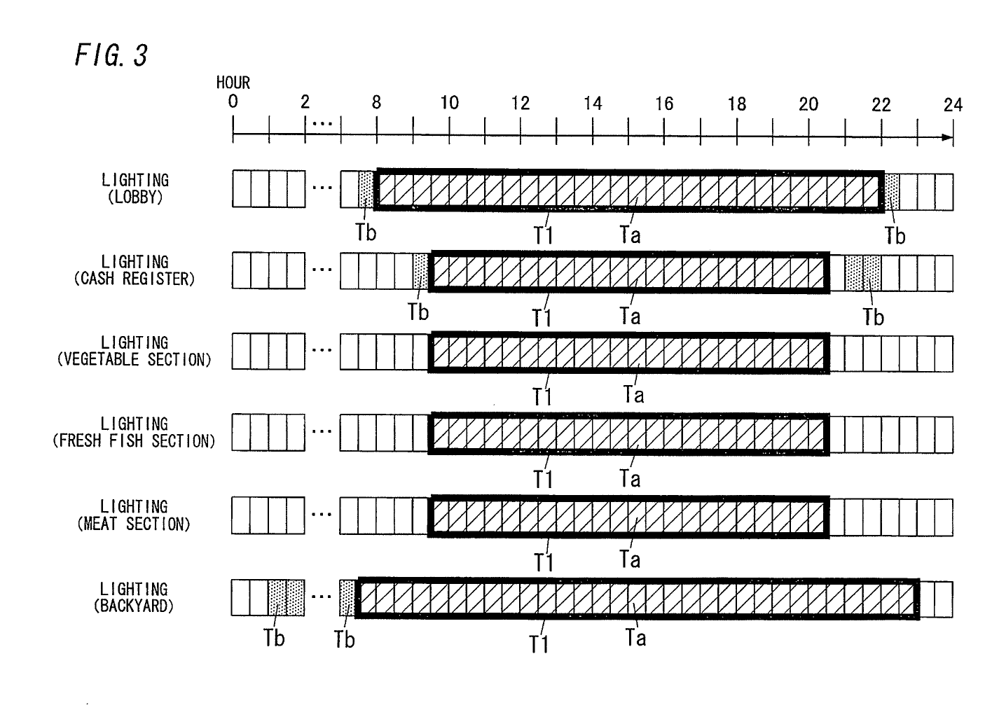

FIG. 3 shows one example of a monitoring screen in the case of a foods supermarket, and represents an electricity usage state of each lighting load 32 from hour 0 (midnight at the start of the day) to hour 24 (midnight at the end of the day). The lighting loads 32 are located at various areas, such as a lobby, a cash register, a vegetable section, a fresh fish section, a meat section and a backyard, in the foods supermarket. The electricity usage state is displayed for each lighting load 32.

In the electricity usage state, a plurality of cells are displayed, each of which is obtained by dividing 24 hours by units of 30 minutes, and are color-coded about whether or not use of electricity at the time period is appropriate. Specifically, cells of a time period corresponding to a usage permission period T1 of each lighting load 32 are surrounded with a frame (in FIG. 3, it is a solid line with which the usage permission period T1 is surrounded). The monitoring screen displays by using different colors with respect to: cells (hereinafter, called an appropriate usage time zone Ta) corresponding to a time period during which the lighting load 32 had used electricity within the usage permission period T1; and cells (hereinafter, called an inappropriate usage time zone Tb) corresponding to time periods during which the lighting load 32 had used electricity out of the usage permission period T1. In the case of FIG. 3, the appropriate usage time zone Ta is represented by diagonal lines and the inappropriate usage time zone m is represented by dots, due to black and white presentation. In addition, cells that correspond to time periods during which electricity had not been used are displayed without colors.

A method for setting the usage permission period is explained below, using a time-management system monitoring the usage periods of electricity used by lighting loads 32 in the foods supermarket, as an example.

First, in the system initial condition, a case is considered, where data of the usage permission period is not stored in the plan memory 12f. In this initial condition, it is considered that, by the user operation to the operating portion 22 of the user terminal 2, data of the usage permission period is generated for each lighting load 32 separately and is stored in the plan memory 12f of the relay control device 1. However, generating data of the usage permission period for each of all lighting loads 32 individually requires a huge amount of work. Therefore, there is a possibility that the setting omission for some lighting loads 32 is occurred.

So, in the present embodiment, by the user operation to the operating portion 22 of the user terminal 2 in this initial condition, data of one collective usage permission period T11 is generated based on the operation form of the foods supermarket and is transmitted to the relay control device 1. In this case, the operation form of the foods supermarket means opening hours “an opening time=10:00 and a closing time=19:00” of the foods supermarket. Then, the collective usage permission period T11 is set as “the starting time=9:30 and the ending time=20:30” including the opening hours of the foods supermarket. That is, the opening hours of the foods supermarket is an operation form for a space (a predetermined space) that is the foods supermarket, and the collective usage permission period T11 is the usage permission period corresponding to the space. The user terminal 2 corresponds to a data generation unit of the invention.

The period setting unit 12e of the relay control device 1 includes a collective setting part 121, a separate setting part 122, a relevance information memory 123, and a relevance information registry 124. The collective setting part 121 receives data of the collective usage permission period T11. The collective setting part 121 determines that the collective usage permission period T11 is the usage permission period corresponding to the space that is the foods supermarket, and relates the collective usage permission period T11 “the starting time=9:30 and the ending time=20:30” to all lighting loads 32, and stores the relationships in the plan memory 12f. The collective usage permission period T11 corresponds to a first usage permission period of the invention.

The determination unit 12c refers to the plan memory 12f, and determines whether or not the usage period of electricity is within the collective usage permission period T11, when the relay 31 is switched on and the lighting load 32 is lit.

The display management unit 12d generates the monitoring image data, in order to display the information relating to the lighting state of each lighting load 32 (the ON/OFF state of each relay 31) together with the determination result of the determination unit 12c through the user terminal 2, and transmits the generated monitoring image data to the user terminal 2 via the terminal side communication unit 11. The user terminal 2 displays the received monitoring image data on the display screen 21 (the monitoring screen).

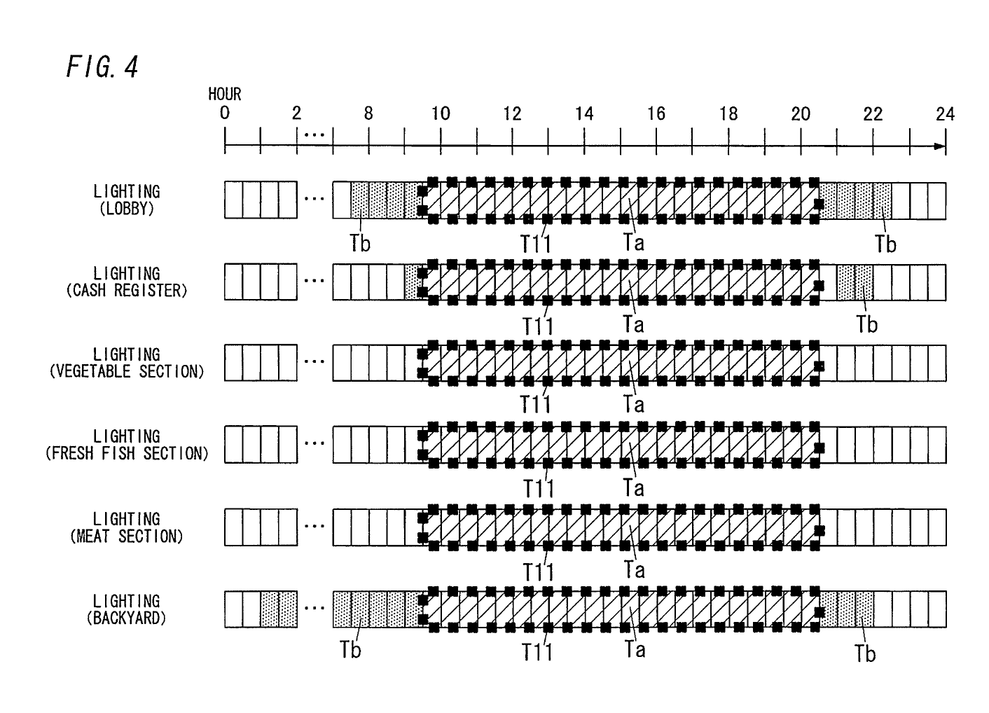

FIG. 4 shows the monitoring screen in the case where the collective usage permission period T11 has been set as the usage permission periods for all lighting loads 32. In this case, the same usage permission period T11 is set to the all lighting loads 32. Cells of a time period corresponding to the collective usage permission period T11 for each lighting load 32 are surrounded with a frame (in FIG. 4, it is a broken line with which the collective usage permission period T11 is surrounded). Furthermore, the appropriate usage time zone Ta in the collective usage permission period T11, and the inappropriate usage time zone Tb out of collective usage permission period T11 are displayed by different colors.

After that, in a case where the operation form (the opening time and the closing time) of the foods supermarket is modified, data of a new collective usage permission period T11 is generated, by the user operation to the operating portion 22 of the user terminal 2, based on the modified operation form of the foods supermarket, and is transmitted to the relay control device 1. The collective setting part 121 of the relay control device 1 relates the new collective usage permission period T11 to all lighting loads 32 and updates data stored in the plan memory 12f. That is, when the collective usage permission period T11 is modified, the modified collective usage permission period T11 is collectively reflected in the usage permission periods for all lighting loads 32, thereby reducing the effort of resetting.

In this way, just by generating a single collective usage permission period T11 based on the operation form of the foods supermarket through the user operation, the same usage permission period T11 is set as the usage permission periods for all lighting loads 32. Therefore, the operational plan can be easily set without omission for each of the lighting loads 32 located in the foods supermarket. Further, the collective usage permission period T11 is set based on the operation form of the foods supermarket, and is applicable to all lighting loads 32 in the foods supermarket, and the operational plans for all lighting loads 32 can be easily set without getting substantially out of an actual lighting time period for each lighting load 32.

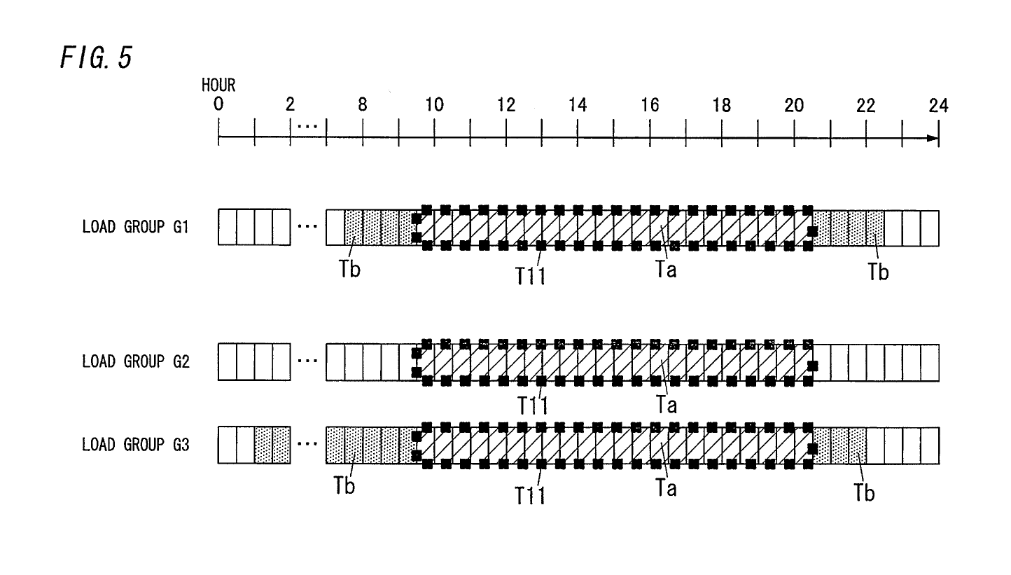

Further, when a plurality of lighting loads 32 are organized into a single load group G for each area, the usage permission period can be also set for each load group G. For example, FIG. 5 shows the monitoring screen in a case where areas are defined in units of floors of an office. In the case of FIG. 5, a load group G1 is constituted by a plurality of lighting loads 32 located at the first and second floors of the office, and a load group G2 is constituted by a plurality of lighting loads 32 located at the third floor of the office, and a load group G3 is constituted by a plurality of lighting loads 32 located at the fourth floor of the office. By setting the same collective usage permission period T11 for all of the load groups G1 to G3, the collective usage permission period T11 is set for each of all lighting loads 32 that belong to the load groups G1 to G3.

In the above-mentioned system with the initial condition, the same collective usage permission period T11 is set as the usage permission periods for all lighting loads 32. Here, the usage permission period can be set (modified) for each lighting load 32, separately. In this case, data of the usage permission period (hereinafter, called a separate usage permission period T12) is generated for each lighting load 32 separately by the user operation to the operating portion 22 of the user terminal 2. The data of the separate usage permission period T12 is transmitted to the relay control device 1. The separate setting part 122 of the relay control device 1 relates the separate usage permission period T12 to the lighting load 32 being the object of the modification, and updates data stored in the plan memory 12f. The separate usage permission period T12 corresponds to a second usage permission period of the invention.

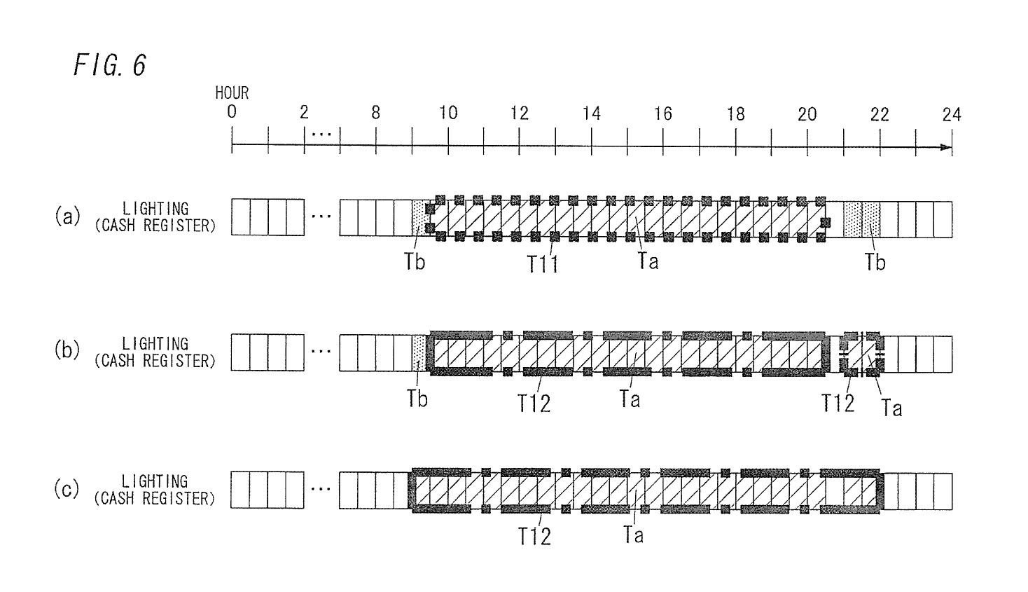

For example, when the usage permission period for a lighting load 32 located at the cash register shown in FIG. 4 is modified from the collective usage permission period T11 to the separate usage permission period T12, the modification is performed as shown in FIG. 6.

In FIG. 6(b), a new usage permission period of “a starting time=21:00 and an ending time=22:00” is added to the present usage permission period T11 of “the starting time=9:30 and the ending time=20:30” (see FIG. 6(a)) for the lighting load 32 located at the cash register. In the addition processing, a setting screen that is similar in configuration to that in FIG. 4 is displayed on the display screen 21 of the user terminal 2. On the setting screen, the addition processing is performed by adding a frame representing the new usage permission period with respect to the cells corresponding to the lighting load 32 being the object of setting. Then, the information relating to the setting screen is transmitted to the relay control device 1.

Then, the separate setting part 122 of the relay control device 1 generates the separate usage permission period T12 in which the new usage permission period of “the starting time=21:00 and the ending time=22:00” is added to the present usage permission period of “the starting time=9:30 and the ending time=20:30” for the lighting load 32 located at the cash register. Next, the separate setting part 122 relates the generated separate usage permission period T12 to the lighting load 32 located at the cash register, and updates data stored in the plan memory 12f. Hereinafter, in the monitoring screen and the setting screen, the cells of the time period corresponding to the separate usage permission period T12 for the lighting load 32 located at the cash register are surrounded with a frame (in FIG. 6(b), it is an alternate long and short dash line with which the separate usage permission period T12 is surrounded).

In FIG. 6(c), the present usage permission period of “the starting time=9:30 and the ending time=20:30” (see FIG. 6(a)) for the lighting load 32 located at the cash register is modified to the usage permission period of “the starting time=9:00 and the ending time=22:00” by the user operation to the operating portion 22 of the user terminal 2. In this modification processing, a setting screen that is similar in configuration to that in FIG. 4 is displayed on the display screen 21 of the user terminal 2. On the setting screen, the modification processing is performed by dragging and extending the frame that indicates the present usage permission period for the lighting load 32 being the object of setting. This information on the setting screen is transmitted to the relay control device 1.

Then, the separate setting part 122 of the relay control device 1 generates the separate usage permission period T12 of “the starting time=9:00 and the ending time=22:00”. Next, the separate setting part 122 relates the generated separate usage permission period T12 to the lighting load 32 located at the cash register, and updates data stored in the plan memory 12f. Hereinafter, in the monitoring screen and the setting screen, the cells of the time period corresponding to the separate usage permission period T12 for the lighting load 32 located at the cash register are surrounded with a frame (in FIG. 6(c), it is an alternate long and short dash line with which the separate usage permission period T12 is surrounded).

In this way, “the lighting load 32 to which the separate usage permission period T12 has been set” can be treated in distinction from “the other lighting loads 32 to which the collective usage permission period T11 has been set”, by setting the separate usage permission period T12 for an individual lighting load 32.

In the present embodiment, when the collective usage permission period T11 is modified by the user operation to the operating portion 22 of the user terminal 2, it can be in advance set whether or not the separate usage permission period T12 is modified so as to interlock with the modified content for the collective usage permission period T11. This interlock setting is explained below.

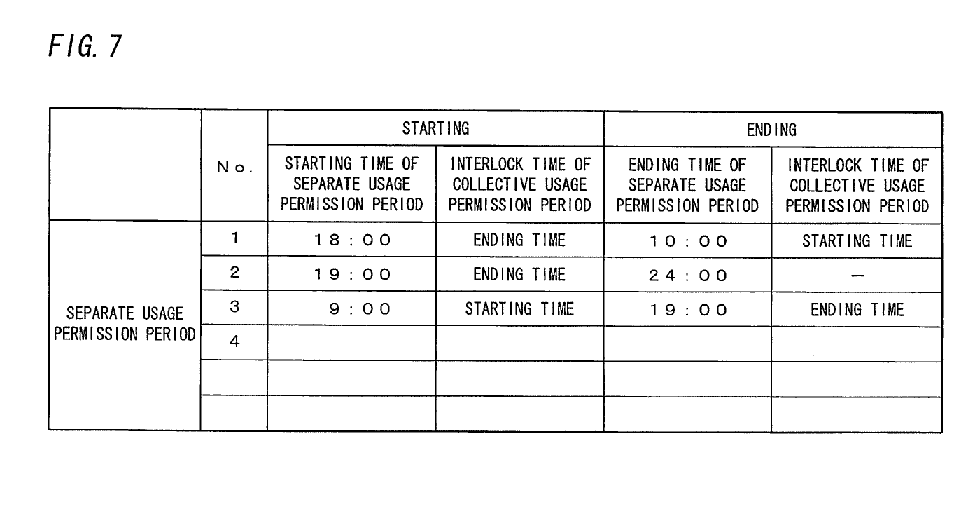

First, the relevance information memory 123 of the relay control device 1 stores relevance information shown in FIG. 7, using a table form. In the relevance information, each of starting times and ending times of the separate usage permission periods T12 is related to a starting time or an ending time of the collective usage permission period T11. The relevance information is generated by the user operation to the operating portion 22 of the user terminal 2, and data of the relevance information is transmitted from the user terminal 2 to the relay control device 1. The relevance information registry 124 of the relay control device 1 registers data of the received relevance information in the relevance information memory 123.

The relevance information shown in FIG. 7 includes: a correspondence relationship between “a starting time of the separate usage permission period T12” and “an interlock time of the collective usage permission period T11”; and a correspondence relationship between “an ending time of the separate usage permission period T12” and “an interlock time of the collective usage permission period T11”, that correspond to an identification number of each separate usage permission period T12 stored in the plan memory 12f.

In regard to fields corresponding to “the starting time of the separate usage permission period T12” and “the interlock time of the collective usage permission period T11”, the present setting value for the starting time of the separate usage permission period T12 is set in each field corresponding to “the starting time of the separate usage permission period T12”. Then, either the starting time or the ending time of the collective usage permission period T11 is set in each field corresponding to “the interlock time of the collective usage permission period T11”, in order to relate the starting time of the separate usage permission period T12 to the starting time or the ending time of the collective usage permission period T11.

In regard to fields corresponding to “the ending time of the separate usage permission period T12” and “the interlock time of the collective usage permission period T11”, the present setting value for the ending time of the separate usage permission period T12 is set in each field corresponding to “the ending time of the separate usage permission period T12”. Either the starting time or the ending time of the collective usage permission period T11 is set in each field corresponding to “the interlock time of the collective usage permission period T11”, in order to relate the ending time of the separate usage permission period T12 to the starting time or the ending time of the collective usage permission period T11.

In a case where “-” is set in a field corresponding to “the interlock time of the collective usage permission period T11”, it means that the starting time or the ending time of the separate usage permission period T12 is related to neither the starting time or the ending time of the collective usage permission period T11.

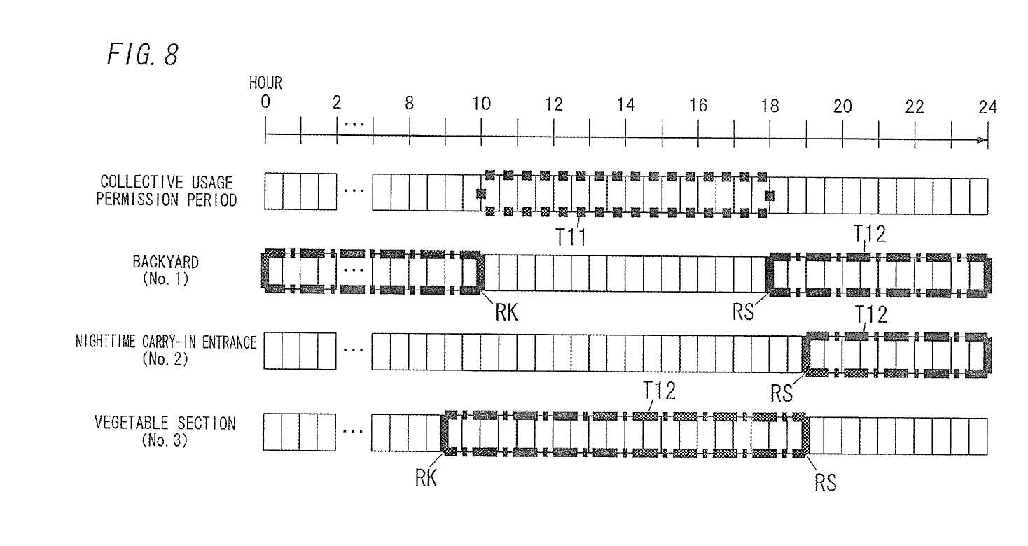

Then, FIG. 8 shows the collective usage permission period T11 and the separate usage permission period T12 that has been set for each of the lighting loads 32 corresponding to the identification numbers “No. 1” to “No. 3”. In this case, the identification number “No. 1” corresponds to a lighting load 32 located at the backyard, and the identification number “No. 2” corresponds to a lighting load 32 located at the nighttime carry-in entrance, and the identification number “No. 3” corresponds to a lighting load 32 located at the vegetable section.

The collective usage permission period T11 is set as “the starting time=10:00 and the ending time=18:00”. The separate usage permission period T12 for the lighting load 32 at the backyard is set as “the starting time=18:00 and the ending time=10:00”. The separate usage permission period T12 for the lighting load 32 at the nighttime carry-in entrance is set as “the starting time=19:00 and the ending time=24:00”. The separate usage permission period T12 for the lighting load 32 at the vegetable section is set as “the starting time=9:00 and the ending time=19:00”.

Here, with respect to the starting times and the ending times of the separate usage permission periods T12 related to the starting time of the collective usage permission period T11, marks “RK” are provided as shown in FIG. 8. Then, with respect to the starting times and the ending times of the separate usage permission periods T12 related to the ending time of the collective usage permission period T11, marks “RS” are provided as shown in FIG. 8.

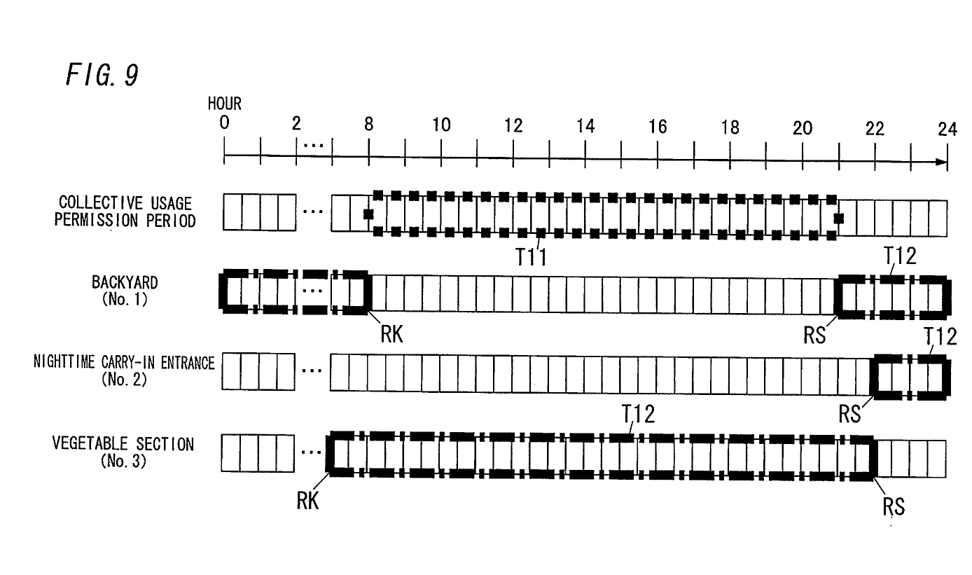

In FIG. 9, the collective usage permission period T11 of “the starting time=10:00 and the ending time=18:00” in the case of FIG. 8 is modified to “the starting time=8:00 and the ending time=21:00”. In this case, the modification of the collective usage permission period T11 is performed by the collective setting part 121. On the other hand, the separate setting part 122 refers to the relevance information stored in the relevance information memory 123, and performs the following interlock setting.

The separate setting part 122 reflects a time difference “−2 hours” (hereinafter, called a starting time difference) between the starting times before and after the modification of the collective usage permission period T11, in the starting times and the ending times of the separate usage permission periods T12 related to the starting time of the collective usage permission period T11. Further, the separate setting part 122 reflects a time difference “+3 hours” (hereinafter, called an ending time difference) between the ending times before and after the modification of the collective usage permission period T11, in the starting times and the ending times of the separate usage permission periods T12 related to the ending time of the collective usage permission period T11.

Specifically, in regard to the separate usage permission period T12 that has been set to the lighting load 32 at the backyard, the starting time thereof is related to the ending time of the collective usage permission period T11, and the ending time thereof is related to the starting time of the collective usage permission period T11.

Accordingly, the separate setting part 122 shifts the starting time “18:00” of the separate usage permission period T12 for the backyard by the ending time difference “+3 hours”, thereby setting as a new starting time “21:00”. In addition, the separate setting part 122 shifts the ending time “10:00” of the separate usage permission period T12 for the backyard by the starting time difference “−2 hours”, thereby setting as a new ending time “8:00”.

Therefore, even when the time periods for the collective and separate usage permission periods T11, T12 are set so as to be reversal of each other as the setting for the backyard, the usage permission period fits with actual electricity consumption state, after the interlock setting.

The starting time of the separate usage permission period T12 that has been set to the lighting load 32 at the nighttime carry-in entrance is related to the ending time of the collective usage permission period T11.

Accordingly, the separate setting part 122 shifts the starting time “19:00” of the separate usage permission period T12 for the nighttime carry-in entrance by the ending time difference “+3 hours”, thereby setting as a new starting time “22:00”.

In regard to the separate usage permission period T12 that has been set to the lighting load 32 at the vegetable section, the starting time thereof is related to the starting time of the collective usage permission period T11, and the ending time thereof is related to the ending time of the collective usage permission period T11.

Accordingly, the separate setting part 122 shifts the starting time “9:00” of the separate usage permission period T12 for the vegetable section by the starting time difference “−2 hours”, thereby setting as a new starting time “7:00”. Further, the separate setting part 122 shifts the ending time “19:00” of the separate usage permission period T12 for the vegetable section by the ending time difference “+3 hours”, thereby setting as a new ending time “22:00”.

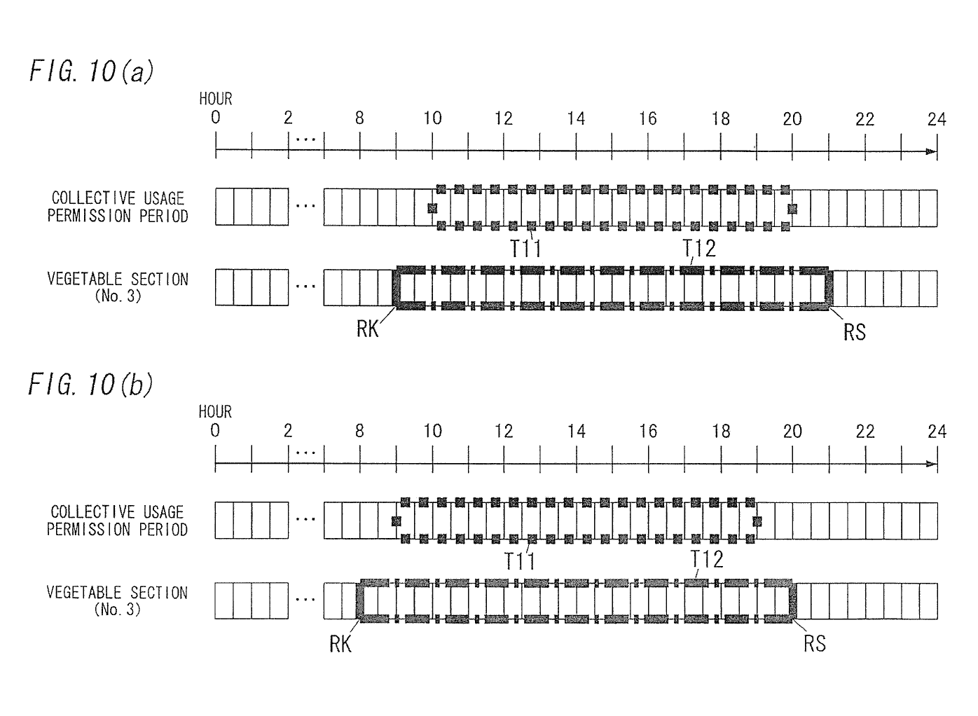

In regard to the interlock setting adapted to daylight-saving time, FIG. 10(a) shows the usage permission periods in winter, and FIG. 10(b) shows the usage permission periods in summer. In winter, the daylight-saving time is not introduced, the collective usage permission period T11 is set as “the starting time=10:00 and the ending time=20:00”, and the separate usage permission period T12 for the vegetable section is set as “the starting time=9:00 and the ending time=21:00”.

In summer, the daylight-saving time is introduced, and the collective usage permission period T11 of “the starting time=10:00 and the ending time=20:00” used for winter is shifted forward by 1 hour. That is, as shown in FIG. 10(b), the collective usage permission period T11 is modified to “the starting time=9:00 and the ending time=19:00”. In this case, the starting time and the ending time of the separate usage permission period T12 for the vegetable section are shifted forward by 1 hour so as to interlock with the modification of the collective usage permission period T11. That is, as shown in FIG. 10(b), the separate usage permission period T12 is modified to “the starting time=8:00 and the ending time=20:00”. Therefore, the interlock setting adapted to the daylight-saving time can be performed.

Also, other interlock patterns, such as an interlock setting depending on climate, can be achieved by relating each of the starting times and the ending times of the separate usage permission periods T12 to the starting time or the ending time of the collective usage permission period T11.

In this way, the present system is available for needs for various interlock patterns in regard to the interlock setting in which the separate usage permission period T12 is modified so as to interlock with modified content for the collective usage permission period T11.

When the starting time or the ending time of the separate usage permission period T12 is related to neither the starting time or the ending time of the collective usage permission period T11, the modified content for the collective usage permission period T11 is not reflected in the separate usage permission period T12.

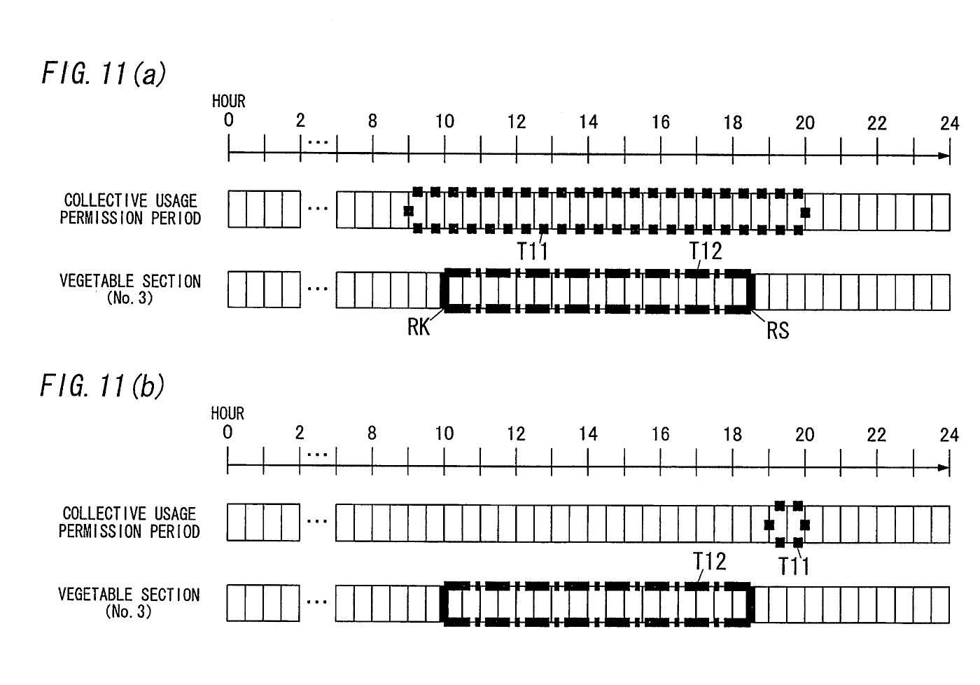

Further, when the collective usage permission period T11 is modified so as to be shortened, the relevance information registry 124 compares the reduced time length for the collective usage permission period T11 with the time length of the separate usage permission period T12. For example, as shown in FIG. 11(a), the collective usage permission period T11 is set as “the starting time=9:00 and the ending time=20:00”, and the separate usage permission period T12 for the vegetable section is set as “the starting time=10:00 and the ending time=18:30”. Here, as shown in FIG. 11(b), when the collective usage permission period T11 is shortened to “the starting time=19:00 and the ending time=20:00”, the reduced time length “10 hours” for the collective usage permission period T11 is more than the time length “8 hours and 30 minutes” of the separate usage permission period T12 for the vegetable section.

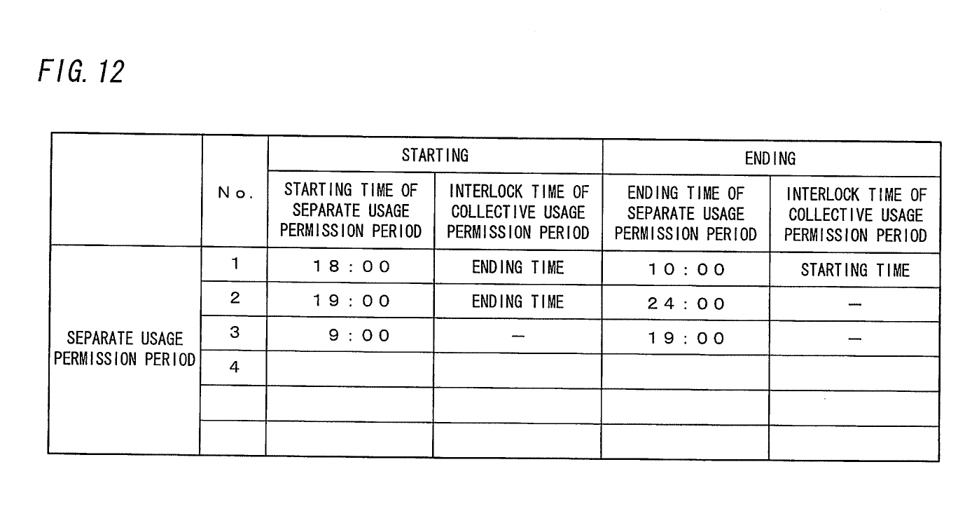

Then, the relevance information registry 124 frees the relationship between the starting time and ending time of the separate usage permission period T12 and the starting time and the ending time of the collective usage permission period T11, when the reduced time length for the collective usage permission period T11 is more than the time length of the separate usage permission period T12. That is, as shown in FIG. 12, the relevance information registry 124 sets “-” in a field corresponding to “the interlock time of the collective usage permission period T11” to which the separate usage permission period T12 for the vegetable section is related, thereby freeing the relationship with the collective usage permission period T11.

In this way, when it becomes impossible to interlock the separate usage permission period T12 with the collective usage permission period T11, the present system frees the relationship between the separate usage permission period T12 and the collective usage permission period T11. Therefore, the operation of the usage permission period can be performed, regardless of the modified content for the collective usage permission period T11.

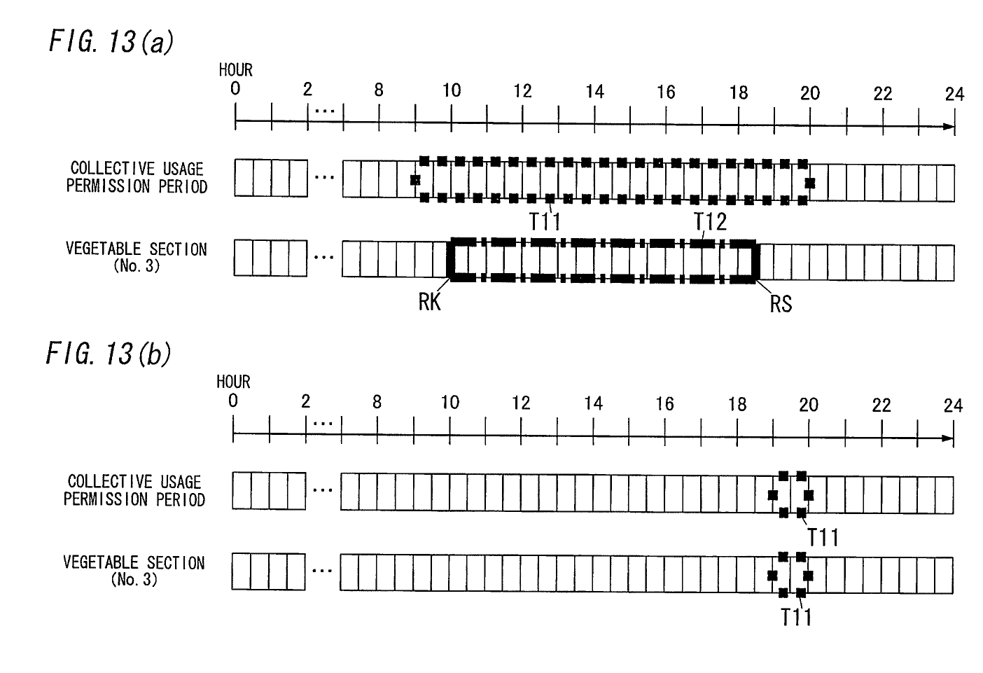

Further, as shown in FIG. 13, the collective setting part 121 may set the collective usage permission period T11 with respect to the vegetable section, when the reduced time length for the collective usage permission period T11 is more than the time length of the separate usage permission period T12 for the vegetable section. That is, when it becomes impossible to interlock the separate usage permission period T12 with the collective usage permission period T11, the separate usage permission period T12 is switched to the collective usage permission period T11. Therefore, the operation of the usage permission period can be performed, regardless of the modified content for the collective usage permission period T11.

Further, the relevance information registry 124 may performs auto-registration of the relevance information to the relevance information memory 123 based on each of setting contents that are set for the starting time and the ending time of the collective usage permission period T11 and the starting times and the ending times of the separate usage permission periods T12, stored in the plan memory 12f.

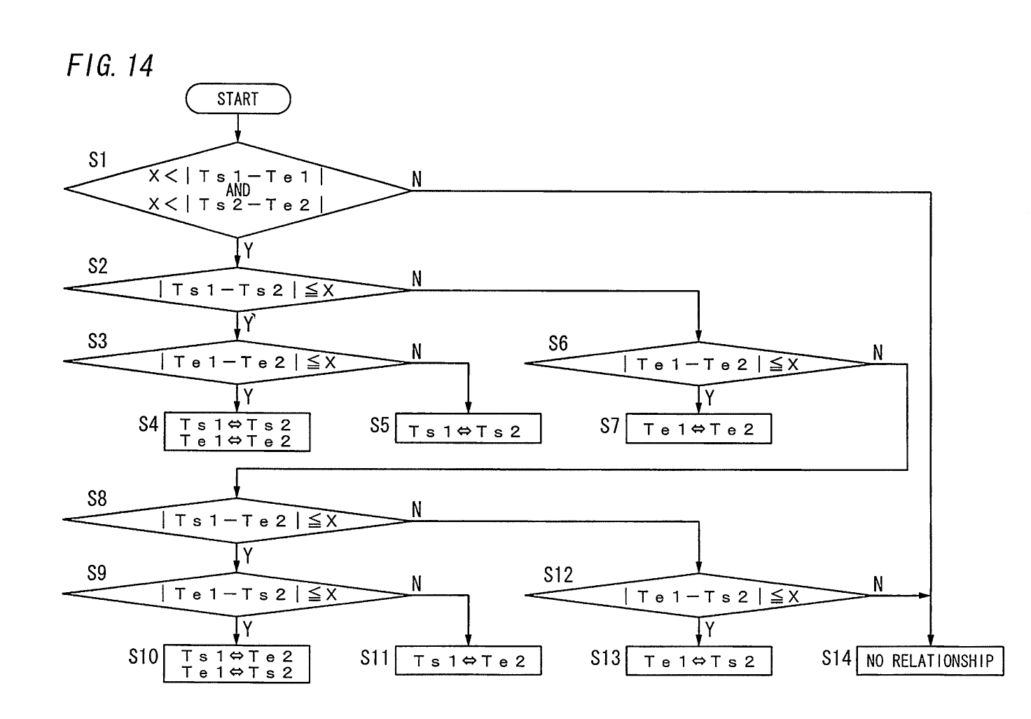

FIG. 14 is a flow chart showing auto-registration processing for the relevance information performed by the relevance information registry 124, where the starting time and ending time of the collective usage permission period T11 are denoted by “Ts1”, “Te1”, respectively, and the starting time and ending time of the separate usage permission period T12 are denoted by “Ts2”, “Te2”, respectively.

First, the relevance information registry 124 calculates a difference |Ts1−Te1| between the starting time T81 and the ending time Te1 of the collective usage permission period T11, and a difference |Ts2−Te2| between the starting time Ts2 and the ending time Te2 of the separate usage permission period T12. Then, the relevance information registry 124 determines whether or not each of differences |Ts1−Te1|, |Ts2−Te2| is more than a predetermined threshold value X (Step S1).

Next, if at least one of the differences |Ts1−Te1|, |Ts2−Te2| is equal to or less than the threshold value X, the relevance information registry 124 does not relate the separate usage permission period T12 to the collective usage permission period T11 (Step S14). On the other hand, if both of the above-mentioned differences exceed the threshold value X, the relevance information registry 124 determines whether or not a difference |Ts1−Ts2| between the starting time Ts1 of the collective usage permission period T11 and the starting time T82 of the separate usage permission period T12 is equal to or less than the threshold value X (Step S2).

In the Step S2, if the difference |Ts1−Ts2| is equal to or less than the threshold value X, the relevance information registry 124 determines whether or not a difference |Ts1−Te2| between the ending time Te1 of the collective usage permission period T11 and the ending time Te2 of the separate usage permission period T12 is equal to or less than the threshold value X (Step S3).

In the Step S3, if the difference |Te1−Te2| is equal to or less than the threshold value X, the relevance information registry 124 relates the starting time Ts2 of the separate usage permission period T12 to the starting time Ts1 of the collective usage permission period T11, and relates the ending time Te2 of the separate usage permission period T12 to the ending time Te1 of the collective usage permission period T11 (Step S4). Further, in the Step S3, if the difference |Te1−Te2| exceeds the threshold value X, the relevance information registry 124 only relates the starting time Ts2 of the separate usage permission period T12 to the starting time Ts1 of the collective usage permission period T11 (Step S5).

On the other hand, in the Step S2, if the difference |Ts1−Ts2| exceeds the threshold value X, the relevance information registry 124 determines whether or not the difference |Te1−Te2| between the ending time Te1 of the collective usage permission period T11 and the ending time Te2 of the separate usage permission period T12 is equal to or less than the threshold value X (Step S6).

In the Step S6, if the difference |Te1−Te2| is equal to or less than the threshold value X, the relevance information registry 124 relates the ending time Te2 of the separate usage permission period T12 to the ending time Te1 of the collective usage permission period T11 (Step S7). Further, in the Step S6, if the difference |Te1−Te2| exceeds the threshold value X, the relevance information registry 124 determines whether or not the difference |Ts1−Te2| between the starting time Ts1 of the collective usage permission period T11 and the ending time Te2 of the separate usage permission period T12 is equal to or less than the threshold value X (Step S8).

In the Step S8, if the difference |Ts1−Te2| is equal to or less than the threshold value X, the relevance information registry 124 determines whether or not the difference |Te1−Te2| between the ending time Te1 of the collective usage permission period T11 and the starting time T82 of the separate usage permission period T12 is equal to or less than the threshold value X (Step S9).

In the Step S9, if the difference |Te1−Ts2| is equal to or less than the threshold value X, the relevance information registry 124 relates the ending time Te2 of the separate usage permission period T12 to the starting time T81 of the collective usage permission period T11, and relates the starting time Ts2 of the separate usage permission period T12 to the ending time Te1 of the collective usage permission period T11 (Step S10). Further, in the Step S9, if the difference |Te1−Ts2| exceeds the threshold value X, the relevance information registry 124 only relates the ending time Te2 of the separate usage permission period T12 to the starting time Ts1 of the collective usage permission period T11 (Step S11).

On the other hand, in the Step S8, if the difference |Ts1−Te2| exceeds the threshold value X, the relevance information registry 124 determines whether or not the difference |Te1−Ts2| between the ending time Te1 of the collective usage permission period T11 and the starting time Ts2 of the separate usage permission period T12 is equal to or less than the threshold value X (Step S12).

In the Step S12, if the difference |Te1−Ts2| is equal to or less than the threshold value X, the relevance information registry 124 relates the starting time Ts2 of the separate usage permission period T12 to the ending time Te1 of the collective usage permission period T11 (Step S13). Further, in the Step S12, if the difference |Te1−Ts2| exceeds the threshold value X, the relevance information registry 124 does not relate the separate usage permission period T12 to the collective usage permission period T11 (Step S14).

As described above, the relevance information registry 124 relates the separate usage permission period T12 to the collective usage permission period T11 based on each time difference between the starting time Ts1 and the ending time Te1 of the collective usage permission period T11 and the starting time Ts2 and the ending time Te2 of the separate usage permission period T12.

When the above-mentioned threshold value X is 2 hours for example, the relevance information registry 124 makes the following relationship. First, if a time difference between the starting time Ts1 of the collective usage permission period T11 and the starting time Ts2 of the separate usage permission period T12 is equal to or less than 2 hours, the relevance information registry 124 relates the starting time Ts2 of the separate usage permission period T12 to the starting time Ts1 of the collective usage permission period T11. Further, if a time difference between the ending time Te1 of the collective usage permission period T11 and the ending time Te2 of the separate usage permission period T12 is equal to or less than 2 hours, the relevance information registry 124 relates the ending time Te2 of the separate usage permission period T12 to the ending time Te1 of the collective usage permission period T11.

If a time difference between the starting time Ts1 of the collective usage permission period T11 and the ending time Te2 of the separate usage permission period T12 is equal to or less than 2 hours, the relevance information registry 124 relates the ending time Te2 of the separate usage permission period T12 to the starting time Ts1 of the collective usage permission period T11. Further, if a time difference between the ending time Te1 of the collective usage permission period T11 and the starting time Ts2 of the separate usage permission period T12 is equal to or less than 2 hours, the relevance information registry 124 relates the starting time Ts2 of the separate usage permission period T12 to the ending time Te1 of the collective usage permission period T11.

As described above, the relevance information registry 124 performs auto-registration of the relevance information to the relevance information memory 123, thereby reducing the trouble required for the registration of the relevance information. Furthermore, the relationships fitting to the actual operation can be set based on each time difference between the starting time and the ending time of the collective usage permission period T11 and the starting time and the ending time of the separate usage permission period T12.

The above-mentioned interlock setting can be also performed with the following configuration: an interlock command is transmitted to the relay control device 1 by the user operation to the operating portion 22 of the user terminal 2 and the separate setting part 122 of the relay control device 1 receives the interlock command.

As explained above, the resource management system is configured to monitor a usage period during which a resource is used by each operation of a plurality of loads located in a predetermined space. The resource management system comprises the information acquisition unit 12b, the data generation unit, the period setting unit 12e, the determination unit 12c, and the display unit. The information acquisition unit 12b is configured to periodically acquire information relating to usage state of the resource. The information relating to the usage state of the resource acquired by the information acquisition unit 12b is defined as usage information. The data generation unit generates data of periods during which use of the resource is permitted. The periods during which use of the resource is permitted are defined as usage permission periods. The period setting unit 12e sets a usage permission period for each of the plurality of loads based on data of the usage permission periods generated by the data generation unit. The determination unit 12c determines whether or not the use of the resource corresponding to the usage information acquired by the information acquisition unit 12b is performed within the usage permission period. Then, the determination unit 12c generates the determination result about whether or not the use of the resource corresponding to the usage information acquired by the information acquisition unit 12b is performed within the usage permission period. The display unit displays the usage period of the resource so as to distinguish whether or not the usage period of the resource is within the usage permission period, using the determination result of the determination unit 12c. The data generation unit generates data of one first usage permission period, and data of one or more second usage permission periods.

The period setting unit 12e comprises the collective setting part 121, the separate setting part 122, the relevance information memory 123, and the relevance information registry 124.

The collective setting part 121 is configured to set the first usage permission period collectively, as usage permission periods for all of the plurality of loads.

More specifically, the collective setting part 121 performs collective setting in which the first usage permission period is collectively set as usage permission periods for all loads except loads to which the second usage permission periods have been set.

That is, the collective setting part 121 does not set the first usage permission period with respect to the loads to which the second usage permission periods have been set, when performing the collective setting.

Here, the first usage permission period includes a starting time and an ending time. That is, the first usage permission period is defined as a period between the starting time and the ending time.

The separate setting part 122 sets the second usage permission periods separately, as usage permission periods for some loads, among the plurality of loads. That is, the separate setting part 122 is configured to perform a separate setting in which the second usage permission periods are separately set as separate usage permission periods for some loads. The relevance information memory 123 is configured to store relevance information that is obtained by relating each of starting times and ending times of the second usage permission periods to a starting time of the first usage permission period. Or, the relevance information memory 123 is configured to store relevance information that is obtained by relating each of starting times and ending times of the second usage permission periods to an ending time of the first usage permission period. The relevance information registry 124 is configured to register the relevance information in the relevance information memory 123.

When the data generation unit modifies the first usage permission period, the separate setting part 122 is configured to modify the starting times and the ending times of the second usage permission periods so as to interlock with modified content for the starting time of the first usage permission period related in the relevance information. Or, when the data generation unit modifies the first usage permission period, the separate setting part 122 is configured to modify the starting times and the ending times of the second usage permission periods so as to interlock with modified content for the ending time of the first usage permission period related in the relevance information.

The information acquisition unit 12b periodically acquires an ON/OFF state of each relay 31, that is, the information relating to the ON/OFF state of each relay 31, thereby monitoring the ON/OFF state of each relay 31. The ON/OFF state of a relay 31 is linked with the lighting state of the corresponding lighting load. Therefore, the information acquisition unit 12b monitors the lighting states of the lighting loads through monitoring the ON/OFF states of the relays 31.

That is, the information acquisition unit 12b monitors information representing the ON/OFF states of the loads that use the resource, thereby periodically acquiring information relating to the usage state of the resource, as the usage information.

The relevance information registry 124 registers the relevance information in the relevance information memory 123 based on each of setting contents that are set for the starting time and the ending time of the first usage permission period and the starting times and the ending times of the second usage permission periods.

FIGS. 8 and 9 show a relationship between the first usage permission period and the backyard (No. 1).

The relevance information memory 123 is configured to store the relevance information obtained by relating the starting time of the second usage permission period to the ending time of the first usage permission period.

When the data generation unit delays the ending time of the first usage permission period, the separate setting part 122 delays the starting time of the second usage permission period. In this way, the separate setting part 122 modifies the staring time of the second usage permission period so as to interlock with the modified content for the ending time of the first usage permission period related in the relevance information.

Here, as described above, in FIGS. 8 and 9, when the data generation unit delays the ending time of the first usage permission period, the separate setting part 122 delays the starting time of the second usage permission period. However when the data generation unit accelerates the ending time of the first usage permission period, the separate setting part 122 may accelerate the starting time of the second usage permission period.

That is, when the data generation unit accelerates the ending time of the first usage permission period, the separate setting part 122 may accelerate the starting time of the second usage permission period, and therefore the separate setting part 122 modifies the staring time of the second usage permission period so as to interlock with the modified content for the ending time of the first usage permission period related in the relevance information.

Then, the relevance information memory 123 is configured to store the relevance information obtained by relating the ending time of the second usage permission period to the starting time of the first usage permission period.

When the data generation unit accelerates the starting time of the first usage permission period, the separate setting part 122 accelerates the ending time of the second usage permission period. In this way, the separate setting part 122 modifies the ending time of the second usage permission period so as to interlock with the modified content for the starting time of the first usage permission period related in the relevance information.

Here, as described above, in FIGS. 8 and 9, when the data generation unit accelerates the starting time of the first usage permission period, the separate setting part 122 accelerates the ending time of the second usage permission period. However when the data generation unit delays the starting time of the first usage permission period, the separate setting part 122 may delay the ending time of the second usage permission period.

That is, when the data generation unit delays the starting time of the first usage permission period, the separate setting part 122 may delay the ending time of the second usage permission period, and therefore the separate setting part 122 modifies the ending time of the second usage permission period so as to interlock with the modified content for the starting time of the first usage permission period related in the relevance information.

Also, FIGS. 8 and 9 show a relationship between the first usage permission period and the vegetable section (No. 3).

The relevance information memory 123 is configured to store the relevance information obtained by relating the starting time of the second usage permission period to the starting time of the first usage permission period. When the data generation unit accelerates the starting time of the first usage permission period, the separate setting part 122 accelerates the starting time of the second usage permission period. In this way, the separate setting part 122 modifies the staring time of the second usage permission period so as to interlock with the modified content for the starting time of the first usage permission period related in the relevance information.

Here, when the data generation unit accelerates the starting time of the first usage permission period in the relationship between the first usage permission period and the vegetable section (No. 3) shown in FIGS. 8 and 9, the separate setting part 122 accelerates the starting time of the second usage permission period. However when the data generation unit delays the starting time of the first usage permission period, the separate setting part 122 may delay the starting time of the second usage permission period.

That is, when the data generation unit delays the starting time of the first usage permission period, the separate setting part 122 may delay the starting time of the second usage permission period, and therefore the separate setting part 122 modifies the starting time of the second usage permission period so as to interlock with the modified content for the starting time of the first usage permission period related in the relevance information.

Then, the relevance information memory 123 is configured to store the relevance information obtained by relating the ending time of the second usage permission period to the ending time of the first usage permission period.

When the data generation unit delays the ending time of the first usage permission period, the separate setting part 122 delays the ending time of the second usage permission period. In this way, the separate setting part 122 modifies the ending time of the second usage permission period so as to interlock with the modified content for the ending time of the first usage permission period related in the relevance information.

Here, as described above, when the data generation unit delays the ending time of the first usage permission period, the separate setting part 122 delays the ending time of the second usage permission period. However when the data generation unit accelerates the ending time of the first usage permission period, the separate setting part 122 may accelerate the ending time of the second usage permission period.

That is, when the data generation unit accelerates the ending time of the first usage permission period, the separate setting part 122 may accelerate the ending time of the second usage permission period, and therefore the separate setting part 122 modifies the ending time of the second usage permission period so as to interlock with the modified content for the ending time of the first usage permission period related in the relevance information.

Further, as shown in FIGS. 8 and 9, the separate setting part 122 includes a shifting means that shifts the starting times and the ending times of the second usage permission periods by a time difference between times before and after the modification for the starting time or the ending time of the first usage permission period related in the relevance information.

When the data generation unit modifies the first usage permission period, the shifting means of the separate setting part 122 shifts the starting times and the ending times of the second usage permission periods by the time difference between times before and after the modification for the starting time of the first usage permission period related in the relevance information.

Then, when the data generation unit modifies the first usage permission period, the shifting means of the separate setting part 122 shifts the starting times and the ending times of the second usage permission periods by the time difference between times before and after the modification for the ending time of the first usage permission period related in the relevance information.

In FIGS. 8 and 9, the starting times and the ending times of the second usage permission periods are shifted by the time difference between times before and after the modification for the starting time or the ending time of the first usage permission period related in the relevance information. However, the shifted starting times and ending times of the second usage permission periods may be more than the time difference. Or, the shifted starting times and ending times of the second usage permission periods may be less than the time difference.

That is, when the data generation unit modifies the first usage permission period, the shifting means of the separate setting part 122 may shift the starting times and the ending times of the second usage permission periods by a time depending on the time difference between times before and after the modification for the ending time of the first usage permission period related in the relevance information.

When the data generation unit modifies the first usage permission period so as to be shortened, if a reduced time length for the first usage permission period is equal to or more than a time length of a second usage permission period among the second usage permission periods, the relevance information registry 124 is configured to free the relationship between the starting time and the ending time of the second usage permission period and the starting time and the ending time of the first usage permission period.

That is, when both of the following first and second conditions are met, the relevance information registry 124 frees the relationship between the starting time and the ending time of the second usage permission period and the starting time and the ending time of the first usage permission period.

The first condition is that the data generation unit modifies the first usage permission period so as to be shortened.

The second condition is that the reduced time length for the first usage permission period is equal to or more than the time length of the second usage permission period.

When the data generation unit modifies the first usage permission period so as to be shortened, if a reduced time length for the first usage permission period is equal to or more than a time length of a second usage permission period, among the second usage permission periods, the collective setting part 121 is configured to set the first usage permission period as the usage permission period for a load corresponding to the second usage permission period. That is, when both of the following first and third conditions are met, the collective setting part 121 sets the first usage permission period as the usage permission period for the load corresponding to the second usage permission period in question.

The first condition is that the data generation unit modifies the first usage permission period so as to be shortened.

The third condition is that the reduced time length for the first usage permission period is equal to or more than the time length of the second usage permission period.

In the above-mentioned embodiment, the resource is not limited to electricity (the amount of electricity), and may be water, gas or heat. Even if such a resource is used, similarly, setting of the usage permission period can be performed.

When the resource is water and gas for example, a water pipe and a gas pipe that respectively provide the water and the gas are located at each area within buildings, such as offices or shops. Then, valves that open and close the water and gas flow channels are located at the water pipes and gas pipes, and the resource management system monitors opening and closing states of the valves, thereby monitoring the usage states (use/non-use) of the water and gas. Also, when the resource is heat, valves that open and close flow channels of the heat medium are located, and the resource management system monitors opening and closing states of the valves, thereby monitoring the usage states (use/non-use) of the heat.

### EXPLANATION OF REFERENCE NUMERALS

1 relay control device
12 controller
12a schedule management unit
12b information acquisition unit
12c determination unit
12d display management unit
12e period setting unit
12f plan memory
121 collective setting part
122 separate setting part
123 relevance information memory
124 relevance information registry
2 user terminal (data generation unit)
21 display screen (display unit)
22 operating portion
3 lighting system
31 relay
32 lighting load

1. A resource management system, monitoring a usage period during which a resource is used by each operation of a plurality of loads located in a predetermined space, comprising:
an information acquisition unit periodically acquiring information relating to usage state of the resource, as usage information;
a data generation unit generating data of usage permission periods during which use of the resource is permitted;
a period setting unit setting a usage permission period for each of the plurality of loads based on data of the usage permission periods generated by the data generation unit;
a determination unit determining whether or not the use of the resource corresponding to the usage information acquired by the information acquisition unit is performed within the usage permission period; and
a display unit displaying the usage period of the resource so as to distinguish whether or not the usage period of the resource is within the usage permission period, using the determination result of the determin-ation unit,
wherein the data generation unit generates data of one first usage permission period, and data of one or more second usage permission periods,
wherein the period setting unit comprises:
a collective setting part setting the first usage permission period collectively, as usage permission periods for all of the plurality of loads;
a separate setting part setting the second usage permission periods separately, as usage permission periods for loads, among the plurality of loads;
a relevance information memory storing relevance information that is obtained by relating each of starting times and ending times of the second usage permission periods to a starting time or an ending time of the first usage permission period; and
a relevance information registry registering the relevance informa-tion in the relevance information memory,
wherein the collective setting part does not set the first usage permission period as usage permission periods for loads to which the second usage permission periods have been set, when performing the collective setting, and
wherein when the data generation unit modifies the first usage permission period, the separate setting part is configured to modify the starting times and the ending times of the second usage permission periods so as to interlock with modified content for the starting time or the ending time of the first usage permission period related in the relevance information.

2. The resource management system according to claim 1,
wherein the relevance information registry registers the relevance information in the relevance information memory based on each of setting contents that are set for the starting time and the ending time of the first usage permission period and the starting times and the ending times of the second usage permission periods.

3. The resource management system according to claim 1,
wherein when the data generation unit modifies the first usage permission period, the separate setting part is configured to shift the starting times and the ending times of the second usage permission periods by a time difference between times before and after the modification for the starting time or the ending time of the first usage permission period related in the relevance information.

4. The resource management system according to claim 3,
wherein when the data generation unit modifies the first usage permission period so as to be shortened, if a reduced time length for the first usage permission period is equal to or more than a time length of a second usage permission period, among the second usage permission periods, the relevance information registry is configured to free the relationship between the starting time and the ending time of the second usage permission period and the starting time and the ending time of the first usage permission period.

5. The resource management system according to claim 3,
wherein when the data generation unit modifies the first usage permission period so as to be shortened, if a reduced time length for the first usage permission period is equal to or more than a time length of a second usage permission period, among the second usage permission periods, the collective setting part is configured to set the first usage permission period as the usage permission period for a load corresponding to the second usage permission period.

6. The resource management system according to claim 2,
wherein when the data generation unit modifies the first usage permission period, the separate setting part is configured to shift the starting times and the ending times of the second usage permission periods by a time difference between times before and after the modification for the starting time or the ending time of the first usage permission period related in the relevance information.

7. The resource management system according to claim 6,
wherein when the data generation unit modifies the first usage permission period so as to be shortened, if a reduced time length for the first usage permission period is equal to or more than a time length of a second usage permission period, among the second usage permission periods, the relevance information registry is configured to free the relationship between the starting time and the ending time of the second usage permission period and the starting time and the ending time of the first usage permission period.

8. The resource management system according to claim 4,
wherein when the data generation unit modifies the first usage permission period so as to be shortened, if a reduced time length for the first usage permission period is equal to or more than a time length of a second usage permission period, among the second usage permission periods, the collective setting part is configured to set the first usage permission period as the usage permission period for a load corresponding to the second usage permission period.

9. The resource management system according to claim 6,
wherein when the data generation unit modifies the first usage permission period so as to be shortened, if a reduced time length for the first usage permission period is equal to or more than a time length of a second usage permission period, among the second usage permission periods, the collective setting part is configured to set the first usage permission period as the usage permission period for a load corresponding to the second usage permission period.

10. The resource management system according to claim 7,
wherein when the data generation unit modifies the first usage permission period so as to be shortened, if a reduced time length for the first usage permission period is equal to or more than a time length of a second usage permission period, among the second usage permission periods, the collective setting part is configured to set the first usage permission period as the usage permission period for a load corresponding to the second usage permission period.
